(19) United States
(12) Patent Application Publication
(10) Pub. No.: US 2025/0173477 A1
(43) Pub. Date: May 29, 2025

(54) LAYOUT ANALYSIS METHOD AND MASK MANUFACTURING METHOD INCLUDING THE LAYOUT ANALYSIS METHOD

(71) Applicant: Samsung Electronics Co., Ltd., Suwon-si (KR)

(72) Inventors: Jeeeun JUNG, Suwon-si (KR); Hun KANG, Suwon-si (KR); Sangwook KIM, Suwon-si (KR); Sanghun KIM, Suwon-si (KR); Heungsuk OH, Suwon-si (KR)

(73) Assignee: Samsung Electronics Co., Ltd., Suwon-si (KR)

(21) Appl. No.: 18/958,594

(22) Filed: Nov. 25, 2024

(30) Foreign Application Priority Data
Nov. 27, 2023 (KR) 10-2023-0167152

(51) Int. Cl. G06F 30/17

(52) U.S. Cl. CPC G06F 30/17

(57) ABSTRACT

A layout analysis method includes segmenting a layout pattern into a plurality of polygons in a shape of a rectangle, extracting a conversion characteristic value by applying tolerance to a characteristic value, the characteristic value comprising shape information of each of the plurality of polygons, extracting a total hash value of each of the plurality of polygons by using the conversion characteristic value of each of the plurality of polygons, grouping patterns of the plurality of polygons into a plurality of groups based on the total hash value of each of the plurality of polygons, and extracting a unique pattern from each of the groups.

### CROSS-REFERENCE TO RELATED APPLICATION

This application is based on and claims priority under 35 U.S.C. § 119 to Korean Patent Application No. 10-2023-0167152, filed on Nov. 27, 2023, in the Korean Intellectual Property Office, the disclosure of which is incorporated by reference herein in its entirety.

### BACKGROUND

The inventive concepts relate to layout analysis methods and mask manufacturing methods including the layout analysis method, and to methods of efficiently analyzing a layout.

In a semiconductor process, a photolithography process using a mask may be performed to form a pattern on a semiconductor substrate, such as a wafer. Simply defined, a mask may be a pattern transfer body in which a pattern shape of an opaque material is formed on a transparent base layer material. To briefly explain a mask manufacturing process, first, the required circuit is designed and a layout for the circuit is designed, and then, mask design data obtained through optical proximity correction (OPC) is transmitted as mask tape-out (MTO) design data. Thereafter, mask data preparation (MDP) is performed based on the MTO design data, and front end of line (FEOL) such as exposure process and back end of line (BEOL) such as defect inspection are performed, and thus, the mask may be manufactured.

### SUMMARY

Some example embodiments of the inventive concepts provide layout analysis methods capable of efficiently analyzing a layout and/or mask manufacturing methods including the layout analysis method.

In addition, problems to be solved by the inventive concepts is not limited to the problems mentioned above, and other problems may be clearly understood by those skilled in the art from the description below.

According to an aspect of the inventive concepts, a layout analysis method may include segmenting a layout pattern into a plurality of polygons in the shape of a rectangle, extracting a conversion characteristic value by applying tolerance to a characteristic value, the characteristic value including shape information of each of the plurality of polygons, extracting a total hash value of each of the plurality of polygons by using the conversion characteristic value of each of the plurality of polygons, grouping patterns of the plurality of polygons into a plurality of groups based on the total hash value of each of the plurality of polygons, and extracting a unique pattern from each of the groups.

According to another aspect of the inventive concepts, there is provided a layout analysis method implemented by a computer system including at least one processor, which is configured to execute computer-readable instructions included in a memory. The layout analysis method includes segmenting, by the at least one processor, a received layout pattern into a plurality of polygons, calculating, by the at least one processor, a conversion characteristic value by applying tolerance to a width, a height, and one vertex coordinate of each of the plurality of polygons, extracting, by the at least one processor, a plurality of total hash values of the plurality of polygons using the conversion characteristic value of each of the plurality of polygons, grouping, by the at least one processor, patterns of the plurality of polygons into a plurality of groups based on whether the total hash values are same, extracting, by the at least one processor, unique patterns of each of the groups.

According to another aspect of the inventive concepts, a mask manufacturing method may include performing a layout analysis method, performing optical proximity correction (OPC) on a full-chip layout based on layout data obtained through the layout analysis method, transmitting data of an OPC full-chip layout as mask tape-out (MTO) design data, the OPC full-chip layout being a modified full-chip layout obtained as a result of the performing of the OPC to the full-chip layout, preparing mask data based on the MTO design data, and exposing a mask substrate based on the mask data, wherein the performing of the layout analysis method includes segmenting a pattern of the full-chip layout into a plurality of polygons in a shape of a rectangle, extracting a conversion characteristic value by applying tolerance to a characteristic value, the characteristic value including shape information of each of the plurality of polygons, extracting a total hash value of each of the plurality of polygons by using the conversion characteristic value of each of the plurality of polygons, grouping patterns of the plurality of polygons into a plurality of groups based on the total hash value of each of the plurality of polygons, and extracting unique patterns from each of the groups.

### BRIEF DESCRIPTION OF THE DRAWINGS

Example embodiments will be more clearly understood from the following detailed description taken in conjunction with the accompanying drawings in which:

FIG. 1 is a flowchart schematically showing a process of a layout analysis method, according to an example embodiment;

FIG. 2 is an image for explaining an operation of segmenting a layout pattern in the layout analysis method according to an example embodiment;

FIG. 3 is a diagram explaining an operation of extracting a conversion characteristic value in the layout analysis method according to an example embodiment;

FIG. 4 is a flowchart showing detailed operations of extracting the conversion characteristic value in the layout analysis method according to an example embodiment;

FIGS. 5 and 6 are diagrams for explaining the operation of extracting the conversion characteristic value in the layout analysis method according to an example embodiment;

FIG. 7 is a graph showing results of a pattern search evaluation based on unique patterns extracted using the layout analysis method according to an example embodiment;

FIG. 8 is a diagram for explaining a layout analysis system for performing the layout analysis method according to an example embodiment; and

FIG. 9 is a flowchart schematically showing a process of a mask manufacturing method including the layout analysis method according to an example embodiment.

### DETAILED DESCRIPTION

Hereinafter, some example embodiments of the inventive concepts will be described in detail with reference to the attached drawings. The same reference numerals are used for the same components in the drawings, and redundant descriptions thereof are omitted.

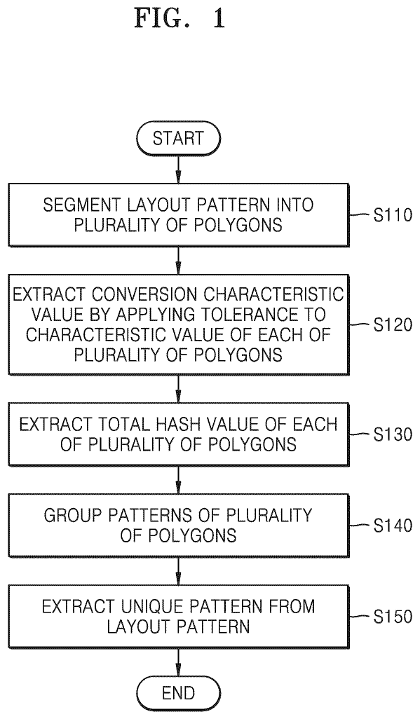

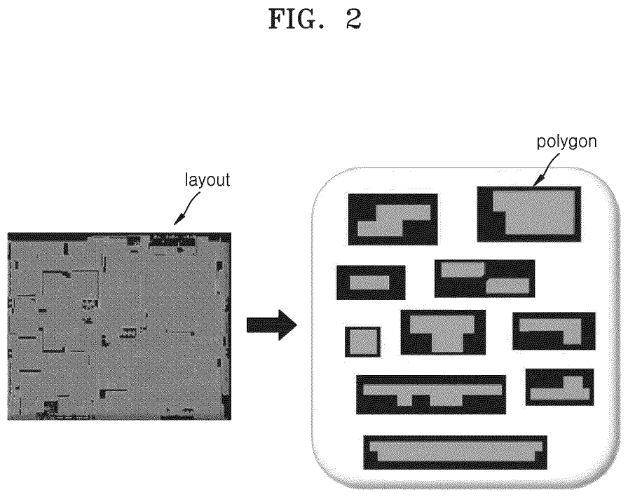

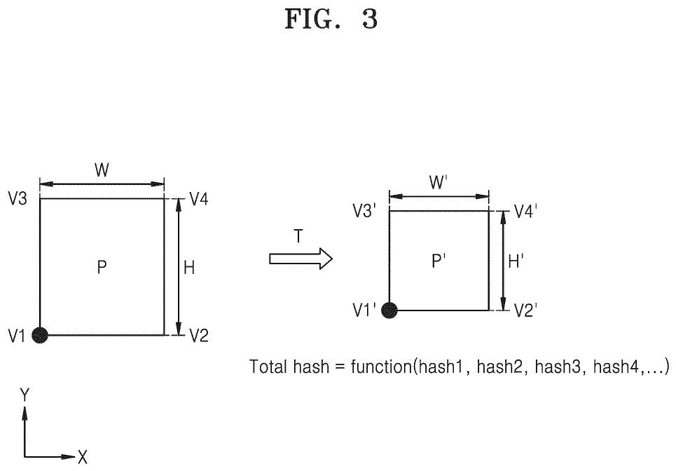

FIG. 1 is a flowchart schematically showing a process of a layout analysis method, according to an example embodiment. FIG. 2 is an image for explaining an operation of segmenting a layout pattern in the layout analysis method according to an example embodiment. FIG. 3 is a diagram for explaining an operation of extracting a conversion characteristic value in the layout analysis method according to an example embodiment.

Referring to FIG. 1, the layout analysis method according to an example embodiment includes operation S110 of segmenting the layout pattern into a plurality of polygons, operation S120 of applying tolerance to a characteristic value of each of the plurality of polygons and extracting the conversion characteristic value (e.g., extracting the conversion characteristic value by applying tolerance to a characteristic value of each of the plurality of polygons), operation S130 of extracting the total hash value of each of the plurality of polygons by using the conversion characteristic value, operation S140 of grouping patterns of the plurality of polygons, and operation S150 of extracting a unique pattern.

Circuit patterns of a semiconductor device may be formed through a process of transferring a pattern on a mask to a substrate such as a wafer using an exposure process. Therefore, the layout of patterns on a mask corresponding to the circuit patterns of the semiconductor device needs to be designed.

The layout analysis method according to an example embodiment first segments the designed layout pattern into the plurality of polygons (S110). For example, the layout pattern is a full-chip layout pattern and may refer to patterns of a single chip.

The image on the left of FIG. 2 shows the full-chip layout pattern, and the image on the right shows some of the plurality of segmented polygons. By cutting the layout pattern according to a desired (or alternatively, preset) command, the layout pattern may be segmented into the plurality of polygons in the shape of a rectangle, as shown in the image of FIG. 2.

Next, the conversion characteristic value is extracted by applying the tolerance to the characteristic value of each of the plurality of segmented polygons (S120). The characteristic value of each of the plurality of polygons may include shape information of the respective polygon. In an example embodiment, when the plurality of polygons each have a rectangular shape, the characteristic value may include the width, height, and one vertex coordinate of a rectangle.

FIG. 3 is a diagram explaining the characteristic value and the conversion characteristic value of one polygon P among the plurality of polygons. Referring to FIG. 3, the characteristic value of the polygon P may include a width W, a height H, and one vertex coordinate (e.g., V1) of the rectangle. Because remaining vertex coordinates V2, V3, and V4 may be obtained by using the one vertex coordinate V1 as the start coordinate and appropriately adding the width W and/or the height H to the start coordinate, the characteristic value may be understood to include the shape information of the polygon P.

The conversion characteristic value may be obtained by applying a certain tolerance T to the above-described characteristic value. The conversion characteristic value may include a conversion width W′, a conversion height H′, and a first coordinate V1′. The conversion width W′ may be calculated by applying the tolerance T to the width W of the polygon P, the conversion height H′ may be calculated by applying the tolerance T to the height H of the polygon P, and the first coordinate V1′ may be calculated by applying the tolerance T to the one vertex coordinate V1 of the polygon P.

In an example embodiment, the conversion width W′, the conversion height H′, and the first coordinate V1′ may form a virtual conversion polygon P′. Expressed differently, the conversion characteristic value may include shape information of the corresponding virtual conversion polygon P′. Because remaining second to fourth vertex coordinates V2′, V3′, and V4′ may be obtained by using the first coordinate V1′ as the start coordinate and appropriately adding the conversion width W′ and the conversion height H′ to the start coordinate, the characteristic value may be understood to include the shape information of the polygon P′.

Specifically, the second coordinate V2′ may be a position spaced apart from the first coordinate V1′ by the conversion width W′ in a first direction (e.g., X direction), the third coordinate V3′ may be a position spaced apart from the first coordinate V1′ by the conversion height H′ in a second direction (e.g., Y direction), and the fourth coordinate V4′ may be a position spaced apart from the second coordinate V2′ by the conversion height H′ in the second direction (e.g., Y direction). The virtual conversion polygon P′ may be a concept for explaining the first to fourth vertex coordinates V1′, V2′, V3′, and V4′ obtained by applying the tolerance T to the characteristic value of the polygon P.

In an example embodiment, the size of the conversion width W′ may be less than the size of the width W, the size of the conversion height H′ may be less than the size of the height H, and the first coordinate V′1 may be closer to the origin than the one vertex coordinate V1. In an example embodiment, the size of the virtual conversion polygon P′ may be less than the size of the polygon P.

Next, the total hash value of each of the plurality of polygons is extracted (S130). The hash value is a hash code and means a bit string output from a hash function. The hash function is a function that maps data of arbitrary length to data of a fixed length, and a value obtained by the hash function is called the hash code, or the hash value in the present specification. The hash function is used in a data structure called a hash table as one of its uses and may be widely used in computer software for very fast data retrieval.

In the present specification, the total hash value may be a value extracted as an output of the hash function with respect to a plurality of hash values. Information of each of the plurality of polygons is represented by one total hash value, and the one total hash value may be extracted as an output of the hash function with respect to first to fourth hash values hash1, hash2, hash3, and hash4, as described below.

The total hash value of each of the plurality of polygons may be extracted by using the above-described conversion characteristic value. Referring to FIG. 3, the total hash value may include information on the first to first to fourth hash values hash1, hash2, hash3, and hash4. Here, the first hash value hash1 may include information of the first coordinate V1′, the second hash value hash2 may include information of the second coordinate V2′, the third hash value hash3 may include information of the third coordinate V3′, and the fourth hash value hash4 may include information of the fourth coordinate V4′. In other words, the total hash value of the polygon P may be extracted by using the information of the vertex coordinates V1′, V2′, V3′, and V4′ of the virtual conversion polygon P′.

Thereafter, the patterns of the plurality of polygons may be grouped into a plurality of groups based on the total hash value of each of the plurality of polygons (S140). The patterns of the plurality of polygons having the same total hash value may be classified into the same group. In other words, all patterns having the same total hash value may be recognized as the same pattern.

Through this, the unique pattern may be extracted from the patterns in each of the plurality of groups (S150). The unique pattern may represent patterns that are repeated among multiple patterns included in the layout and may be distinct from other patterns. Operation S150 of extracting the unique pattern may be an operation of extracting one of the patterns of the plurality of polygons classified into the same group in the grouping operation S140 as a representative pattern. That is, as described above, all patterns having the same total hash value are recognized as the same pattern, and one of the patterns recognized as the same pattern may be extracted as the representative pattern.

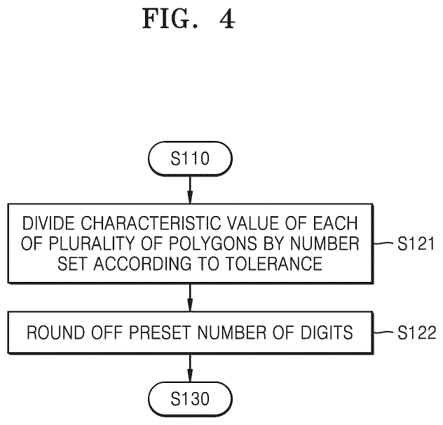

To summarize with reference to FIGS. 1 to 3, the layout analysis method according to an example embodiment may segment the layout corresponding to the semiconductor circuit pattern into the plurality of polygons, and then, apply the tolerance T to the characteristic value (e.g., the width W, the height H, and the vertex coordinate V1) of the polygon P, and obtain the first to fourth coordinates V1′, V2′, V3′, and V4′ of the virtual conversion polygon P′. The layout analysis method according to an example embodiment may extract the total hash value of the polygon P with respect to the first to fourth coordinates V1′, V2′, V3′, and V4′ of the virtual conversion polygon P′, group the plurality of polygons with respect to the total hash value of the polygon P, and extract the unique pattern. Application of the tolerance T is described with reference to FIGS. 4 to 6.

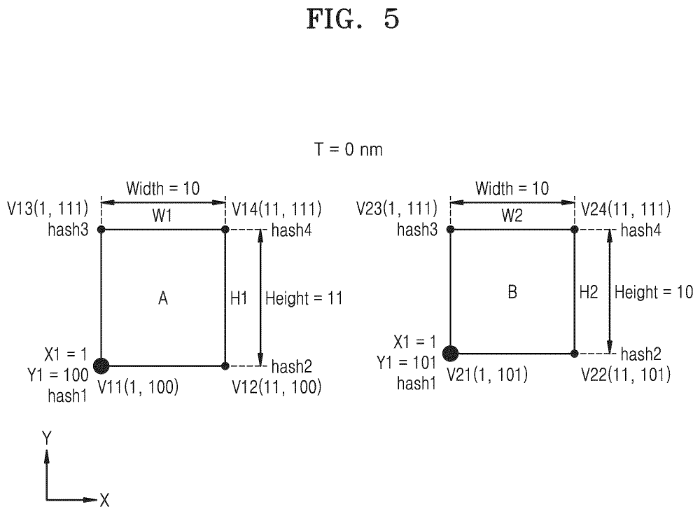

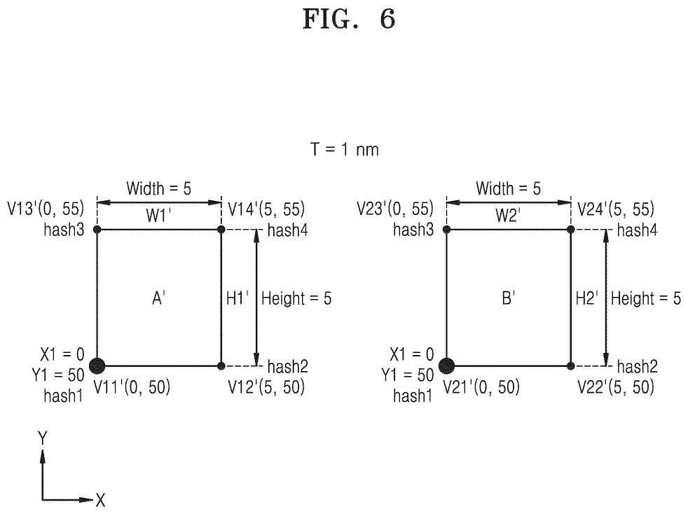

FIG. 4 is a flowchart showing detailed operations of extracting a conversion characteristic value in a layout analysis method according to an example embodiment. FIGS. 5 and 6 are diagrams for explaining an operation of extracting the conversion characteristic value in the layout analysis method according to an example embodiment.

Referring to FIG. 4, in an example embodiment, operation S120 (see FIG. 1) of extracting the conversion characteristic value may include operation S121 of dividing the characteristic value of each of a plurality of polygons by a number set according to tolerance and operation S122 of rounding off a desired (or alternatively, preset) number of digits.

The tolerance is a setting allowable value that serves as a reference for applying the tolerance and may be set considering the sizes of the plurality of polygons. In an example embodiment, the size of the tolerance may be smaller than the minimum value of widths and the minimum value of heights of the plurality of polygons. The size of the tolerance may range from several to tens of nanometers.

The number set according to the tolerance may be expressed without units as a value used to calculate the conversion characteristic value to apply the tolerance. The number set according to tolerance may be a number obtained by adding a certain default value to the tolerance and then deleting a unit. The certain default value may be a default value corresponding to a unit of a characteristic value such as width or height. For example, in order to apply tolerance of 5 nm to a characteristic value in the range of several to tens of nanometers, the number set according to the tolerance may be 6 obtained by adding a default value of 1 mm in a unit of the characteristic value to the tolerance of 5 nm and deleting the unit from 6 nm.

FIG. 5 shows a state before applying the tolerance T to a characteristic value of each of a first polygon A and a second polygon B segmented from the layout pattern. Expressed differently, FIG. 5 shows a case where the tolerance T applied to each of the first polygon A and the second polygon B included in the plurality of polygons is 0 nm, and a number set according to the tolerance T for applying the tolerance T is 1 (adding the default value of 1 nm to the tolerance T of 0 nm and then deleting the unit).

First, referring to FIG. 5, the characteristic values of the first polygon A may include a first width W1, a first height H1, and one vertex coordinate V11. The characteristic values of the second polygon B may include a second width W2, a second height H2, and one vertex coordinate V21. In FIG. 5, the first width W1 is 10 nm, the second width W2 is 10 nm, the first height H1 is 11 nm, and the second height H2 is 10 nm. The vertex coordinate V11 of the first polygon A is (1, 100), and the vertex coordinate V21 of the second polygon B is (1, 101).

In the case of FIG. 5, because the tolerance T is not applied, information of each of vertex coordinates V11, V12, V13, and V14 of the first polygon A and vertex coordinates V21, V22, V23, and V24 of the second polygon B is extracted as a total hash value. At this time, because a Y1 value of the first polygon A is 100, and a Y1 value of the second polygon B is 101 (vertex coordinates do not match each other), the total hash values of the first polygon A and the second polygon B are differently extracted, and accordingly, a pattern of the first polygon A and a pattern of the second polygon B may be classified into different groups.

FIG. 6 shows a virtual first conversion polygon A′ corresponding to a conversion characteristic value in which the tolerance T is applied to the characteristic value of the first polygon A, and a virtual second conversion polygon B′ corresponding to a conversion characteristic value in which the tolerance T is applied to the characteristic value of the second polygon B.

FIG. 6 shows a case where the tolerance T applied to the first polygon A and the second polygon B of FIG. 5 is 1 nm, and a number set according to the tolerance T for applying the tolerance T is 2 (adding the default value of 1 nm to the tolerance T of 1 nm and then deleting the unit). However, example embodiments are not limited thereto, and tolerance T may be set to an appropriate value as needed.

In addition, FIG. 6 illustrates an example in which the same size of tolerance T is applied to all characteristic values, but example embodiments are not limited thereto. For example, unlike FIG. 6, the size of the tolerance T may be modified and applied in various ways, such as applying the tolerance T of 1 nm to the first width W1 and the second width W2, and applying the tolerance T of 2 nm to the first height H1 and the second height H2.

Referring again to FIG. 6, the conversion characteristic value of the first polygon A may include a first conversion width W1′, a first conversion height H1′, and a 1-1 coordinate V11′, and the conversion characteristic value of the polygon B may include a second conversion width W2′, a second conversion height H2′, and a 2-1 coordinate V21′.

The first conversion width W1′ is a value obtained by applying the tolerance T to the first width W1, the first conversion height H1′ is a value obtained by applying the tolerance T to the first height H1, and the 1-1 coordinate V11′ is a value obtained by applying the tolerance T to the vertex coordinate V11. The second conversion width W2′ is a value obtained by applying the tolerance T to the second width W2, the second conversion height H2′ is a value obtained by applying the tolerance T to the second height H2, and the 2-1 coordinate V21′ is a value obtained by applying the tolerance T to the vertex coordinate V21. Hereinafter, a method of extracting the conversion characteristic value is described through examples in FIGS. 5 and 6.

First, according to operation S121 of dividing the characteristic value by a number (here, 2) set according to the tolerance T, the characteristic value of each of the first polygon A and the second polygon B is divided by 2. In the operation of dividing the characteristic value by 2, the first width W1 may be converted into 5 nm, the second width W2 may be converted into 5 nm, the first height H1 may be converted into 5.5 nm, and the second height H2 may be converted into 5 nm. The vertex coordinate V11 of the first polygon A may be converted into (0.5, 50), and the vertex coordinate V21 of the second polygon B may be converted into (0.5, 50.5).

Next, in operation S122 of rounding off the preset number of digits (here, the digits below a decimal point are rounded off), the conversion characteristic value may be extracted by rounding off the digits below the decimal point of each of the characteristic values converted by dividing by 2. In the operation of rounding off the digits below the decimal point, the first conversion width W1′ is extracted as 5 nm, the second conversion width W2′ is extracted as 5 nm, the first conversion height H1′ is extracted as 5 nm, and the second conversion height H2′ is extracted as 5 nm. The 1-1 coordinate V11′ is extracted as (0, 50), and the 2-1 coordinate V21′ is extracted as (0, 50). Accordingly, the first conversion height H1′ and the second conversion height H2′ are equal to each other as 5 nm, and the 1-1 coordinate V11′ and the 2-1 coordinate V21′ are equal to each other as (0, 50). As such, through the rounding off operation (S122), values with slight differences may be corrected to have the same value.

In the example of FIG. 6, the first polygon A and the second polygon B may have the same total hash value according to the respective conversion characteristic values thereof.

Specifically, the 1-1 coordinate V11′ of the virtual first conversion polygon A′ is (0, 50), the 1-2 coordinate V12′ is (5, 50) spaced by the first conversion width W1′ from the 1-1 coordinate V11′ in the first direction (e.g., X direction), the 1-3 coordinate V13′ is (0, 55) spaced by the first conversion height H1′ from the 1-1 coordinate V11′ in the second direction (e.g., Y direction), and the 1-4 coordinate V14′ is (5, 55) spaced apart from the 1-2 coordinate V12′ by the first conversion height H1′ in the second direction (e.g., Y direction).

The 2-1 coordinate V21′ of the virtual second conversion polygon B′ is (0, 50), the 2-2 coordinate V22′ is (5, 50) spaced apart from the 2-1 coordinate V21′ by the second conversion width W2′ in the first direction (e.g., X direction), the 2-3 coordinate V23′ is (0, 55) spaced apart from the 2-1 coordinate V21′ by the second conversion height H2′ in the second direction (e.g., Y direction), and the 2-4 coordinate V24′ is (5, 55) spaced apart from the 2-2 coordinate V22′ by the second conversion height H2′ in the second direction (e.g., Y direction).

That is, the vertex coordinates V11′, V12′, V13′, and V14′ of the virtual first conversion polygon A′ have the same values as the vertex coordinates V21′, V22, V23′, and V24′ of the virtual second conversion polygon B′, respectively.

As described above with reference to FIG. 3, the vertex coordinates V11′, V12′, V13′, and V14′ of the virtual first conversion polygon A′ correspond to the first to fourth hash values hash1, hash2, hash3, and hash4 of the first polygon A, respectively, and the vertex coordinates V21′, V22′, V23′, and V24′ of the virtual second conversion polygon B′ correspond to the first to fourth hash values hash1, hash2, hash3, and hash4 of the second polygon B, respectively. The total hash value of each of the first polygon A and the second polygon B may be extracted as an output of a hash function with respect to the first to fourth hash values hash1, hash2, hash3, and hash4. Accordingly, the total hash value of the first polygon A and the total hash value of the second polygon B may be extracted equally.

In the layout analysis method according to an example embodiment, the scale of each of the plurality of polygons may be reduced through dividing operation S121 and rounding off operation S122 so that slight size differences between the polygons are treated equally. The tolerance may be applied so that the plurality of polygons having differences within a certain range have the same total hash value, and a unique pattern may be extracted by grouping patterns of the plurality of polygons with respect to or based on the total hash value of each of the plurality of polygons. Compared to classifying patterns using a separate post-processing method after extracting the total hash value of each polygon without applying the tolerance, example embodiments may efficiently classify the patterns of the plurality of polygons.

According to example embodiments, the patterns of the plurality of polygons having differences within the certain range are classified into the same group, and thus, the number of unique patterns may be reduced. In addition, when sampling is performed by selecting some of the unique patterns extracted according to example embodiments, various types of patterns may be sampled with a relatively small number of unique patterns and pattern coverage may be improved.

Table 1 below shows results of a pattern search evaluation based on the unique patterns extracted by the layout analysis method according to some example embodiments compared with the case of Comparative Example Ref. Table 1 shows Embodiment 1 (T=5 nm) and Embodiment 2 (T=10 nm) in which different tolerances are applied when the unique patterns are extracted.

TABLE 1

| | Ref | T = 5 nm | T = 10 nm |
|---|---|---|---|
| Runtime (sec) | 7460.35 | 7411.1 | 7160.34 |
| No. of unique patterns (ea) | 547414 | 447227 | 398160 |
| Area of unique | 257.56 | 290.01 | 357.52 |
| patterns (um²) | (0.0017%) | (0.0019%) | (0.0024%) |

Runtimes, the number of unique patterns, and areas of unique patterns in the results of the pattern search evaluation of Comparative Example Ref, Embodiment 1 (T=5 nm), and Embodiment 2 (T=10 nm) are described with reference to Table 1 above. In Comparative Example Ref, 547414 unique patterns are found in the runtime of 7460.35 seconds, through which the area of 257.56 um² may be covered.

In Embodiment 1 (T=5 nm), a conversion characteristic value is obtained by applying tolerance of 5 nm to each of characteristic values of polygons, and unique patterns are extracted through the conversion characteristic value, and thus, 447227 unique patterns may be found in a runtime of 7411.1 seconds and an area of 290.01 um² may be covered. In Embodiment 2 (T=10 nm), a conversion characteristic value is obtained by applying tolerance of 10 nm to each of the characteristic values of the polygons, and unique patterns are extracted through the conversion characteristic value, and thus, 398160 unique patterns may be searched in a runtime of 7160.34 seconds, and an area of 357.52 um² may be covered.

In Embodiment 1 (T=5 nm) and Embodiment 2 (T=10 nm), a pattern occupying a larger area may be searched with fewer unique patterns than Comparative Example Ref without increasing runtime. That is, Embodiment 1 (T=5 nm) and Embodiment 2 (T=10 nm) in which the unique patterns are extracted by applying the tolerance, may secure an increased pattern coverage compared to Comparative Example Ref in which the unique patterns are extracted by not applying the tolerance.

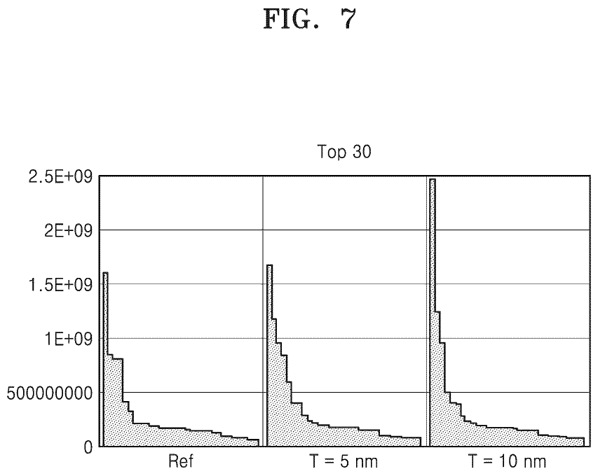

FIG. 7 is a graph showing results of a pattern search evaluation based on unique patterns extracted using a layout analysis method according to an example embodiment.

FIG. 7 is a bar graph of the results of searching for 30 unique patterns in the order of the number of patterns included in each unique pattern in Comparative Example Ref, Embodiment 1 (T=5 nm), and Embodiment 2 (T=10 nm) in Table 1, where the x-axis represents each unique pattern, and the y-axis represents the number of patterns included in each unique pattern. As shown in FIG. 7, when the same number (here, 30) of unique patterns are found, Embodiment 1 (T=5 nm) and Embodiment 2 (T=10 nm) include more patterns than Comparative Example Ref.

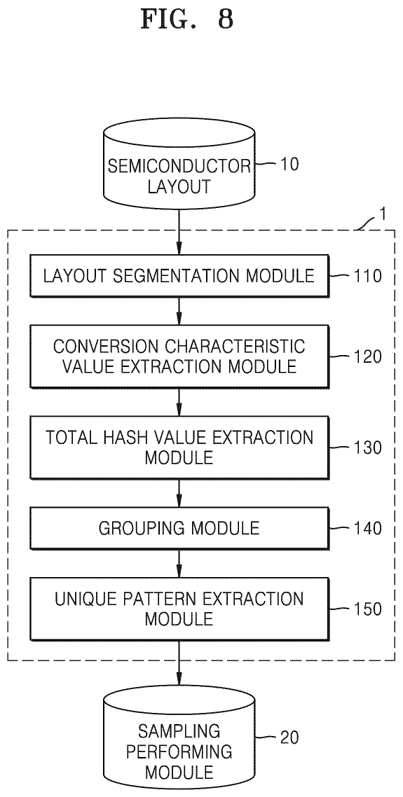

FIG. 8 is a diagram for explaining a layout analysis system 1 for performing the layout analysis method according to an example embodiment.

Referring to FIG. 8, the layout analysis system 1 may include a layout segmentation module 110, a conversion characteristic value extraction module 120, a total hash value extraction module 130, a grouping module 140, and a unique pattern extraction module 150.

The layout segmentation module 110 may receive a designed semiconductor layout 10 and segment a layout pattern into a plurality of polygons in the shape of a rectangle. The semiconductor layout 10 may be a full-chip layout.

The conversion characteristic value extraction module 120 may extract a conversion characteristic value of each of the plurality of polygons segmented by the layout segmentation module 110. The conversion characteristic value extraction module 120 may calculate the conversion characteristic value by applying tolerance to the width, height, and one vertex coordinate of each of the plurality of polygons. The size of the tolerance may be set considering the size of each of the plurality of polygons. In an example embodiment, the size of the tolerance may range from several to tens of nanometers, and in this case, the conversion characteristic value may be calculated by dividing each of the width, the height, and the one vertex coordinate of each of the plurality of polygons by a set number, and then rounding off digits below a decimal point in nanometer units.

The total hash value extraction module 130 may extract the total hash value by using the conversion characteristic value extracted from the conversion characteristic value extraction module 120. The total hash value may be obtained using vertex coordinates of a virtual conversion polygon corresponding to the conversion characteristic value.

The grouping module 140 may group patterns of the plurality of polygons with respect to the total hash value of each of the plurality of polygons. The grouping module 140 may classify the patterns of the plurality of polygons having the same total hash value into the same group.

The unique pattern extraction module 150 may extract unique patterns of patterns of the semiconductor layout 10. The unique pattern extraction module 150 may extract one of the patterns of the plurality of polygons classified into the same group by the grouping module 140 as a representative pattern.

A sampling performing module 20 may perform sampling using the unique pattern extracted through the layout analysis method of the layout analysis system 1. The sampling performing module 20 may perform sampling by selecting some unique patterns from among the unique patterns extracted by the unique pattern extraction module 150. Sampling data may be used in a variety of ways, such as machine learning, optical proximity correction (OPC), DB analysis, etc.

The layout segmentation module 110, the conversion characteristic value extraction module 120, a total hash value extraction module 130, the grouping module 140, and the unique pattern extraction module 150 may be representations of different functions performed by at least one processor in response to an instruction provided from a memory installed in or associated with the layout analysis system 1. The sampling performance module 20 may also be a representations of a function performed by at least one processor in response to an instruction from a computer.

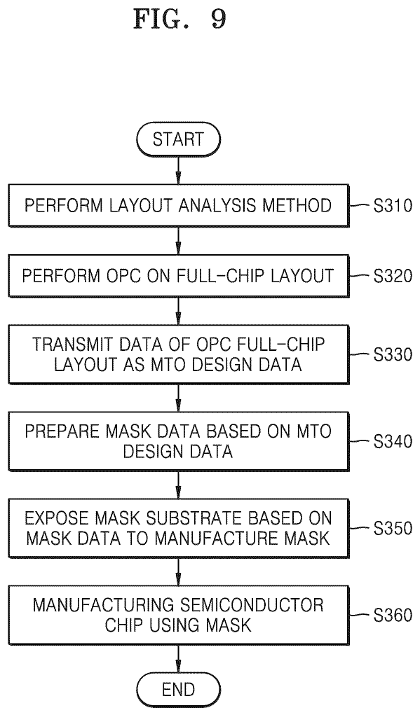

FIG. 9 is a flowchart schematically showing a process of a mask manufacturing method including a layout analysis method according to an example embodiment.

Referring to FIG. 9, the mask manufacturing method according to an example embodiment includes operation S310 of performing the layout analysis method, operation S320 of performing OPC on a full-chip layout, operation S330 of transmitting data of the OPC full-chip layout, which is a modified full-chip layout obtained as a result of performing the OPC to the full-chip layout, as mask tape-out (MTO) design data, operation S340 of preparing mask data based on the MTO design data, operation S350 of exposing a mask substrate based on the mask data to manufacture a mask, and operation S360 of manufacturing a semiconductor chip using the mask.

Referring to FIG. 9, the mask manufacturing method including the layout analysis method of the aforementioned example embodiment (hereinafter, simply referred to as the ‘mask manufacturing method’) first performs the layout analysis method (S310). The layout analysis method is the same as previously described with reference to FIGS. 1 to 8.

Briefly, in operation S310 of performing the layout analysis method, a layout pattern is first segmented into a plurality of polygons as described with reference to FIG. 2.

A conversion characteristic value is extracted by applying tolerance to a characteristic value of each of the plurality of segmented polygons. When a polygon has a rectangular shape, the characteristic value may include the width, height, and one vertex coordinate of the rectangle. The conversion characteristic value may include a conversion width, a conversion height, and a first coordinate obtained by applying the tolerance to each of the width, the height, and the one vertex coordinate. The conversion characteristic value may be obtained by dividing the characteristic value of each of the plurality of polygons by a set number and then rounding off a preset number of digits. In an example embodiment, the tolerance is in units of several to tens of nanometers, and when extracting the conversion characteristic value, the tolerance may be calculated by rounding off digits below a decimal point in nanometer units.

The total hash value of each of the plurality of polygons is extracted using the conversion characteristic value. The total hash value may be extracted as an output of a hash function with respect to first to fourth hash values, and the first to fourth hash values may include information of four vertex coordinates of a rectangle (e.g., the virtual conversion polygon P′ in FIG. 3) corresponding to the conversion characteristic value.

Patterns are grouped with respect to the total hash value, and unique patterns are extracted with respect to the patterns. When each of the plurality of polygons has the same total hash value, the patterns may be classified into the same group and recognized as the same pattern. The unique patterns may be extracted by extracting one of the patterns classified into the same group as a representative pattern.

Referring to FIG. 9, after operation S310 of performing the layout analysis method, OPC is performed on a full-chip layout (S320). As the patterns become smaller, an optical proximity effect (OPE) may occur due to influences between neighboring patterns during an exposure process. To alleviate or overcome this, OPC correcting a mask layout and suppressing the occurrence of the OPE may be performed. OPC may include a process of generating an optical image of a corresponding pattern, generating an OPC model, and obtaining an image or data of the mask layout through simulation using the OPC model.

OPC may be broadly divided into two types. One is rule-based OPC, and the other is simulation-based or model-based OPC. Model-based OPC may be advantageous in terms of time and cost because model-based OPC uses only measurement results of some patterns without having to measure all of a large number of test patterns. In addition, OPC may include a method of not only modifying the mask layout but also adding sub-lithographic features called serifs on corners of the pattern, or a method of adding sub-resolution assist features (SRAFs) such as scattering bars.

OPC performed in the mask manufacturing method according to an example embodiment may be model-based OPC. OPC may perform modeling using some sample patterns, and in this case, and, at this time, the sample pattern may be obtained by performing sampling from the unique patterns extracted in operation S310 of performing the layout analysis method. That is, OPC may be performed based on layout data obtained through the layout analysis method.

In an example embodiment, in operation S320 of performing OPC, sampling may be performed by selecting m unique patterns (where m is a natural number less than n) in order of increasing number of patterns included in each of n unique patterns (where n is a natural number of 2 or more) extracted in operation S310 of performing the layout analysis method and may be performed based on a plurality of sample patterns corresponding to the m unique patterns.

When OPC is performed using the layout data obtained through the layout analysis method according to an example embodiment, as described above with reference to FIGS. 1 to 8, samples of various patterns may be extracted with a small number of unique patterns, and pattern coverage may be improved, and thus, more accurate OPC may be performed.

OPC is generally described as follows. First, basic data for OPC is prepared. Here, the basic data may include data of shapes of the sample patterns, positions of the patterns, the type of measurement such as measurement of a space or line of the pattern, basic measurement values, etc. In addition, the basic data may include information such as the thickness, refractive index, and dielectric constant of photoresist (PR), and may include a source map with respect to the shape of an illumination system. The basic data is not limited to the data described above.

After preparing the basic data, an optical OPC model is generated. Generation of the optical OPC model may include optimization of a defocus stand (DS) position, a best focus (BF) position, etc. in an exposure process. In addition, the generation of the optical OPC model may include generation of an optical image considering a diffraction phenomenon of light or an optical state of exposure equipment itself. The generation of the optical OPC model is not limited to the above description. For example, the generation of the optical OPC model may include various descriptions related to the optical phenomenon in the exposure process.

After generating the optical OPC model, an OPC model with respect to the PR is generated. Generation of the OPC model with respect to the PR may include optimization of a threshold value of the PR. Here, the threshold value of the PR is a threshold value at which a chemical change occurs during the exposure process and for example, may be given as the intensity of exposure light. Generation of the OPC model with respect to the PR may also include selecting an appropriate model form from several PR model forms.

The optical OPC model and the OPC model with respect to the PR are generally referred to as the OPC model. After generating the OPC model, simulation using the OPC model is repeated. Simulation may be performed until certain conditions are satisfied. For example, a root mean square (RMS) with respect to a CD error, EPE, reference number of repetitions, etc. may be used as repetition conditions for simulation.

Thereafter, data of the OPC full-chip layout is transmitted to a mask manufacturing team as the MTO design data (S330). The MTO may mean handing over final mask data obtained through an OPC method to the mask manufacturing team to request mask manufacturing. Accordingly, the MTO design data may be substantially the same as the data of the OPC full-chip layout. The MTO design data may have a graphic data format used in electronic design automation (EDA) software, etc. For example, the MTO design data may have a data format such as graphic data system II (GDS2), open artwork system interchange standard (OASIS), etc.

Thereafter, mask data preparation (MDP) is performed (S340). MDP may include, for example, i) format conversion, called fracturing, ii) augmentation of barcodes for mechanical reading, a standard mask pattern for inspection, a job deck, etc., and iii) automatic and manual verification. Here, the job-deck may mean creating a text file regarding a series of instructions such as arrangement information of multiple mask files, standard dose, exposure speed or method, etc.

The term “format conversion” (e.g., fracturing) may refer to a process of dividing the MTO design data into each region and changing the MTO design data to a format for an electron beam exposure machine. Fracturing may include data manipulation, such as scaling, sizing of data, rotation of data, pattern reflection, color inversion, etc. In a conversion process through fracturing, data may be corrected with respect to numerous systematic errors that may occur somewhere during a transfer from design data to images on a wafer. The data correction process with respect to the systematic errors is called mask process correction (MPC) and may include, for example, jobs adjusting a line width which is called CD adjustment and increasing the precision of pattern arrangement. Therefore, fracturing may contribute to improving the quality of the final mask and may also be a process that is performed in advance for MPC. Here, the systematic errors may be caused by distortion occurring in an exposure process, a mask development and etching process, a wafer imaging process, etc.

In addition, MDP may include MPC. As described above, MPC refers to a process of correcting errors that occur during the exposure process, that is, systematic errors. Here, the exposure process may include electron beam writing, development, etching, baking, etc. In addition, data processing may be performed prior to the exposure process. Data processing is a kind of preprocessing process on mask data and may include grammar check for the mask data, exposure time prediction, etc. Through MDP, E-beam data to expose a mask substrate may be generated.

After MDP, the mask substrate is exposed using the mask data (e.g., the E-beam data) (S350). Here, exposure may mean, for example, E-beam writing. Here, E-beam writing may be performed, for example, through gray writing using a multi-beam mask writer (MBMW). In addition, E-beam writing may also be performed using a variable shape beam (VSB) exposure machine.

Moreover, after MDP and before the exposure process, a process of converting the E-beam data into pixel data may be performed. The pixel data is data directly used for actual exposure and may include data of shapes to be exposed and data of a dose of the E-beam assigned to each shape. Here, the data of the shape may be bit-map data obtained by converting shape data, which is vector data, through rasterization, etc.

After the exposure process, a series of processes may be performed to complete the mask. The series of processes may include, for example, development, etching, and cleaning processes. In addition, the series of processes for mask manufacturing may include a metrology process, defect inspection, or defect repair process. In addition, a pellicle application process may be included. Here, the pellicle application process may refer to a process of attaching a pellicle to a mask surface to protect the mask from subsequent contamination during delivery of the mask and during the useful life of the mask, when it is confirmed through final cleaning and inspection that there are no contaminant particles or chemical stains.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While the inventive concepts have been particularly shown and described with reference to some example embodiments thereof, it will be understood that various changes in form and details may be made therein without departing from the spirit and scope of the following claims.

What is claimed is:

1. A layout analysis method comprising:
segmenting a layout pattern into a plurality of polygons in a shape of a rectangle;
extracting a conversion characteristic value by applying tolerance to a characteristic value, the characteristic value comprising shape information of each of the plurality of polygons;
extracting a total hash value of each of the plurality of polygons by using the conversion characteristic value of each of the plurality of polygons;
grouping patterns of the plurality of polygons into a plurality of groups based on the total hash value of each of the plurality of polygons; and
extracting a unique pattern from each of the groups.

2. The layout analysis method of claim 1, wherein the extracting of the conversion characteristic value includes:
dividing the characteristic value of each of the plurality of polygons by a number set according to the tolerance; and
subsequently rounding off a number of digits.

3. The layout analysis method of claim 2, wherein the characteristic value of each of the plurality of polygons includes a width, a height, and one vertex coordinate of the rectangle.

4. The layout analysis method of claim 3, wherein a size of the tolerance is less than a minimum value of widths and a minimum value of heights of the plurality of polygons.

5. The layout analysis method of claim 3, wherein the conversion characteristic value includes a conversion width calculated by applying the tolerance to the width, a conversion height calculated by applying the tolerance to the height, and a first coordinate calculated by applying the tolerance to the one vertex coordinate.

6. The layout analysis method of claim 5, wherein
a size of the conversion width is less than a size of the width, a size of the conversion height is less than a size of the height, and the first coordinate is closer to an origin than the one vertex coordinate.

7. The layout analysis method of claim 5, wherein
the conversion width, the conversion height, and the first coordinate form a virtual conversion polygon, and
vertexes of the virtual conversion polygon include the first coordinate, a second coordinate spaced apart from the first coordinate by the conversion width in a first direction, a third coordinate spaced apart from the first coordinate by the conversion height in a second direction perpendicular to the first direction, and a fourth coordinate spaced apart from the second coordinate by the conversion height in the second direction.

8. The layout analysis method of claim 7, wherein
a total hash value of each of the plurality of polygons is extracted as an output of a hash function with respect to a first hash value, a second hash value, a third hash value, and a fourth hash value,
the first hash value corresponds to the first coordinate, the second hash value corresponds to the second coordinate, the third hash value corresponds to the third coordinate, and the fourth hash value corresponds to the fourth coordinate.

9. The layout analysis method of claim 1, wherein the grouping of the patterns of the plurality of polygons includes classifying the patterns of the plurality of polygons having a same total hash value into a same group.

10. The layout analysis method of claim 1, wherein the extracting of the unique pattern includes extracting one of the patterns of the plurality of polygons classified into a same group as a representative pattern.

11. A layout analysis method implemented by a computer system including at least one processor, which is configured to execute computer-readable instructions included in a memory, the method comprising:
segmenting, by the at least one processor, a received layout pattern into a plurality of polygons;
calculating, by the at least one processor, a conversion characteristic value by applying tolerance to a width, a height, and one vertex coordinate of each of the plurality of polygons;
extracting, by at least one processor, a plurality of total hash values of the plurality of polygons using the conversion characteristic value of each of the plurality of polygons;
grouping, by the at least one processor, patterns of the plurality of polygons into a plurality of groups based on whether the total hash values of each of the plurality of polygons are same; and
extracting, by the at least one processor, unique patterns of each of the groups.

12. The layout analysis method of claim 11, wherein a size of the tolerance ranges from several to tens of nanometers.

13. The layout analysis method of claim 12, wherein the at least one processor is configured to calculate the conversion characteristic value by dividing each of the width, the height, and the one vertex coordinate by a number set according to the tolerance, and then rounding off digits below a decimal point in nanometer units.

14. The layout analysis method of claim 11, further comprising:
performing sampling, by the at least one processor, by selecting some unique patterns from among the unique patterns.

15. A mask manufacturing method comprising:
performing a layout analysis method;
performing optical proximity correction (OPC) on a full-chip layout based on layout data obtained through the layout analysis method;
transmitting data of an OPC full-chip layout as mask tape-out (MTO) design data, the OPC full-chip layout being a modified full-chip layout obtained as a result of the performing of the OPC to the full-chip layout;
preparing mask data based on the MTO design data; and
exposing a mask substrate based on the mask data,
wherein the performing of the layout analysis method comprises,
segmenting a pattern of the full-chip layout into a plurality of polygons in a shape of a rectangle,
extracting a conversion characteristic value by applying tolerance to a characteristic value, the characteristic value comprising shape information of each of the plurality of polygons,
extracting a total hash value of each of the plurality of polygons by using the conversion characteristic value of each of the plurality of polygons,
grouping patterns of the plurality of polygons into a plurality of groups based on the total hash value of each of the plurality of polygons, and
extracting unique patterns from each of the groups.

16. The mask manufacturing method of claim 15, wherein the performing of the OPC includes performing sampling by selecting m unique patterns (where m is a natural number less than n) in order of increasing number of patterns included in each of n unique patterns (where n is a natural number of 2 or more) extracted in the extracting.

17. The mask manufacturing method of claim 16, wherein the performing of the OPC includes performing of the OPC based on a plurality of sample patterns corresponding to the m unique patterns.

18. The mask manufacturing method of claim 15, wherein the characteristic value of each of the plurality of polygons includes a width, a height, and one vertex coordinate of the rectangle.

19. The mask manufacturing method of claim 18, wherein the conversion characteristic value includes a conversion width, a conversion height, and a first coordinate calculated by dividing each of the width, the height, and the one vertex coordinate by a number set according to the tolerance, and then rounding off a number of digits.

20. The mask manufacturing method of claim 19, wherein the total hash value includes information of four vertex coordinates of a virtual conversion polygon corresponding to the conversion width, the conversion height, and the first coordinate.
